(19) United States
(12) Patent Application Publication
(10) Pub. No.: US 2023/0058110 A1
(43) Pub. Date: Feb. 23, 2023

(54) NON-VOLATILE MEMORY DEVICES WITH MULTI-LAYERED FLOATING GATES

(71) Applicant: GLOBALFOUNDRIES Singapore Pte. Ltd., Singapore (SG)

(72) Inventors: KHEE YONG LIM, Singapore (SG); KIAN MING TAN, Singapore (SG)

(21) Appl. No.: 17/405,037

(22) Filed: Aug. 18, 2021

(51) Int. Cl. H01L 29/423; H01L 29/788; H01L 21/28; H01L 29/66

(52) U.S. Cl. CPC H01L 29/42328; H01L 29/7883; H01L 29/40114; H01L 29/66825

(57) ABSTRACT

A non-volatile memory device is provided. The non-volatile memory device includes a substrate, a floating gate, and a gate. The substrate includes a source region and a drain region, and a channel region between the source region and the drain region. The floating gate is over the channel region. The floating gate includes a first conductive layer and a second conductive layer underlying the first conductive layer. The gate is adjacent to the floating gate.

### TECHNICAL FIELD

The present disclosure relates generally to semiconductor devices, and more particularly to non-volatile memory devices with multi-layered floating gates and methods of forming the same.

### BACKGROUND

Memory devices are widely used in semiconductor chips and can be generally divided into volatile memory devices and non-volatile memory (NVM) devices. Volatile memory devices, such as a static random access memory (SRAM) device, require a supply of electric power to retain stored data but lose the data when the supply of electric power is interrupted. On the other hand, NVM devices, such as flash memory devices, retain the stored data even without a supply of electric power.

The NVM devices may utilize a charge retention mechanism to store data. For example, charges may be stored in a floating gate of an NVM device during a program operation and the stored charges may be expelled from the floating gate during an erase operation.

As the semiconductor industry continues to progress, NVM devices having improved performance and methods of forming the same are provided.

### SUMMARY

To achieve the foregoing and other aspects of the present disclosure, non-volatile memory (NVM) devices with multi-layered floating gates and methods of forming the same.

According to an aspect of the present disclosure, a non-volatile memory device is provided. The non-volatile memory device includes a substrate, a floating gate, and a gate. The substrate includes a source region and a drain region, and a channel region between the source region and the drain region. The floating gate is over the channel region. The floating gate includes a first conductive layer and a second conductive layer underlying the first conductive layer. The gate is adjacent to the floating gate.

According to another aspect of the present disclosure, a non-volatile memory device is provided. The non-volatile memory device includes a substrate, a floating gate, a first gate, and a second gate. The substrate includes a source region and a drain region, and a channel region between the source region and the drain region. The floating gate is over the channel region. The floating gate includes a first side and a second side laterally opposite the first side. The floating gate further includes a first conductive layer having a first width and a second conductive layer having a second width underlying the first conductive layer, and the first width is narrower than the second width. The first gate is adjacent to the first side of the floating gate and the second gate is adjacent to the second side of the floating gate.

According to yet another aspect of the present disclosure, a method of forming a non-volatile memory device is provided. The method includes forming a source region in a substrate and forming a drain region in the substrate spaced apart from the source region by a channel region therebetween. A floating gate is formed over the channel region and the floating gate has a first width and a second width. A first gate and a second gate are formed over then at laterally opposite sides of the floating gate.

### BRIEF DESCRIPTION OF THE DRAWINGS

The embodiments of the present disclosure will be better understood from a reading of the following detailed description, taken in conjunction with the accompanying drawings.

FIG. 1 is a cross-sectional view of a non-volatile memory device, according to an embodiment of the disclosure.

FIG. 2 is a cross-sectional view of a non-volatile memory device, according to another embodiment of the disclosure.

FIG. 3 is a cross-sectional view of a non-volatile memory device, according to yet another embodiment of the disclosure.

FIGS. 4A to 4F are cross-sectional views that illustrate a method of forming a memory cell of the non-volatile memory device in FIG. 1, according to an embodiment of the disclosure.

FIG. 5 is a cross-sectional view of a non-volatile memory device, according to an alternative embodiment of the disclosure.

FIG. 6 is a cross-sectional view of a non-volatile memory device, according to another alternative embodiment of the disclosure.

For simplicity and clarity of illustration, the drawings illustrate the general manner of construction, and certain descriptions and details of features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to semiconductor devices, and more particularly to non-volatile memory (NVM) devices with multi-layered floating gates and methods of forming the same. The NVM device may include a memory cell that utilizes a floating gate as a charge retention mechanism to store charges. Exemplary embodiments of NVM devices include a flash memory cell, an erasable programmable read-only memory (EPROM) cell, and an electrically erasable and programmable read-only memory (EEPROM) cell.

Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure.

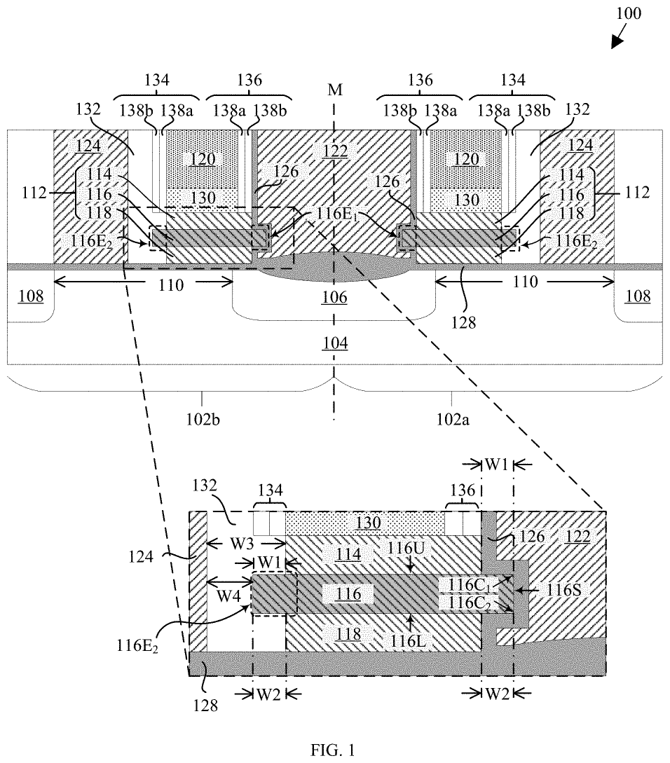

FIG. 1 is a cross-sectional view of an NVM device 100, according to an embodiment of the disclosure. The NVM device 100 may be positioned in a memory cell region of a semiconductor device and the NVM device 100 may be part of a plurality of NVM devices positioned in an array configuration of rows and columns in the memory cell region. Only one NVM device is illustrated for clarity purposes.

The NVM device 100 may include a plurality of memory cells, for example, a memory cell 102a and a memory cell 102b positioned adjacent to the memory cell 102a. The memory cell 102a and the memory cell 102b may be mirror images of each other, i.e., the memory cell 102a may have mirror symmetry about an axis M through the center of the NVM device 100. However, the NVM device 100 may not need to include both the memory cell 102a and the memory cell 102b. For example, the NVM device 100 may include the memory cell 102a or the memory cell 102b. In an embodiment of the disclosure, the NVM device 100 may be referred to as a 1.5 T memory device having a split-gate architecture.

The NVM device 100 may be fabricated over a substrate 104. The substrate 104 may include a plurality of doped regions, for example, a source region 106 and a plurality of drain regions 108. The source region 106 and the plurality of drain regions 108 may be at least partially arranged in the substrate 104. In an embodiment of the disclosure, the source region 106 may be a shared source region between the memory cell 102a and the memory cell 102b. Between the source region 106 and the drain region 108 is a channel region 110, which provides a path for the conduction of charges therebetween.

Each memory cell 102a and 102b may include a floating gate 112. The floating gate 112 may be arranged over and electrically isolated from the substrate 104. The floating gate 112 may be at least partially arranged over the channel region 110. For example, a portion of the floating gate 112 may be arranged over the channel region 110, and another portion of the floating gate 112 may be arranged over the source region 106, as illustrated in FIG. 1. In another example, the floating gate 112 may be arranged over the entire channel region 110, even though this embodiment is not illustrated in the accompanying drawings.

The floating gate 112 may include a multi-layered structure. For example, the floating gate 112 may include at least a conductive layer 114 and a conductive layer 116 underlying the conductive layer 114. The conductive layer 114 may have a width narrower than that of the conductive layer 116. The floating gate 112 may further include a conductive layer 118 underlying the conductive layer 116 such that the conductive layer 116 may be between the conductive layer 114 and the conductive layer 118, as illustrated in FIG. 1. Similar to the conductive layer 114, the conductive layer 118 may have a width narrower than that of the conductive layer 116.

The conductive layer 114 and the conductive layer 116 may include different conductive materials such that the conductive layer 114 may have a substantially high etch selectivity with respect to the conductive layer 116. The conductive layer 118 may also include a different conductive material such that the conductive layer 118 may have a substantially high etch selectivity with respect to the conductive layer 116. The conductive layer 114 and the conductive layer 118 may not necessarily include the same conductive material and may include different conductive materials, as long as the conductive layer 114 and the conductive layer 118 have a substantially high etch selectivity with respect to the conductive layer 116.

The term “etch selectivity” as used herein refers to the material removal rate of one material relative to the material removal rate of another material, for example, the ratio of the material removal rate of the conductive layer 114 to the material removal rate of the conductive layer 116. The term “substantially high etch selectivity” as used herein refers to a characteristic between two materials, such that one material may be removed without substantially removing the other material. For example, the etch selectivity of the conductive layer 114 with respect to the conductive layer 116 may be in a ratio of 100:1, such that for every 100 nm of the material removed from the conductive layer 114, only 1 nm of the material of the conductive layer 116 is removed. Therefore, the conductive layer 116 may be removed at a relatively much slower rate or remain substantially intact during the material removal process.

In an embodiment of the disclosure, the conductive layer 114 may include a conductive material such as polycrystalline silicon germanium. In another embodiment of the disclosure, the conductive layer 116 may include a conductive material such as polycrystalline silicon. In yet another embodiment of the disclosure, the conductive layer 118 may include a conductive material such as polycrystalline silicon germanium.

The conductive layer 116 may have a width wider than the conductive layer 114 such that an end portion 116E₁ of the conductive layer 116 may extend beyond the conductive layer 114 by a width W1. The end portion 116E₁ of the conductive layer 116 may also extend beyond the conductive layer 118 by a width W2. In an embodiment of the disclosure where the conductive layer 114 and the conductive layer 118 are formed of the same conductive material, the width W1 may be substantially equal to the width W2.

The conductive layer 116 may include a side surface 116S, an upper surface 116U, and a lower surface 116L; the side surface 116S may be arranged substantially perpendicular to the upper surface 116U and the lower surface 116L. The conductive layer 116 may further include a corner 116C₁ formed at the end portion 116E₁ at a junction of the side surface 116S and the upper surface 116U. The conductive layer 116 may further yet include a corner 116C₂ formed at the end portion 116E₁ at a junction of the side surface 116S and the lower surface 116L.

The conductive layer 116 may include another end portion 116E₂ laterally opposite the end portion 116E₁. The end portion 116E₂ may extend beyond the conductive layer 114 by the width W1. The end portion 116E₂ of the conductive layer 116 may also extend beyond the conductive layer 118 by the width W2.

The NVM device 100 may further include a control gate 120, an erase gate 122, and a select gate 124. The control gate 120 may be arranged over and electrically isolated from the floating gate 112. The erase gate 122 and the select gate 124 may be arranged over and electrically isolated from the substrate 104 and at laterally opposite sides of the floating gate 112 and the control gate 120, such that the floating gate 112 and the control gate 120 may be arranged therebetween and electrically isolated therefrom.

The erase gate 122 may be at least partially arranged over the source region 106 and adjacent to the floating gate 112. The erase gate 122 may be arranged over the end portion 116E₁ of the conductive layer 116 of the floating gate 112 such that the erase gate 122 may at least partially overlay the corner 116C₁ of the conductive layer 116, and the corner 116C₁ of the conductive layer 116 may point towards the erase gate 122. The erase gate 122 may acquire a concave side surface adjacent to the floating gate 112.

The erase gate 122 may further at least partially overlay the corner 116C₂ of the conductive layer 116 such that the corner 116C₂ of the conductive layer 116 may point towards the erase gate 122. In an embodiment of the disclosure where the conductive layer 116 has two corners, i.e., the corner 116C₁ and the corner 116C₂, the erase gate 122 may at least partially overlay the end portion 116E₁ of the conductive layer 116 of the floating gate 112.

The NVM device 100 may yet further include a tunnel barrier layer 126. The tunnel barrier layer 126 may be arranged between the erase gate 122 and the floating gate 112. The tunnel barrier layer 126 may be conformal to a side surface of the conductive layer 114, the side surface 116S of the conductive layer 116, and a side surface of the conductive layer 118. The tunnel barrier layer 126 may overlay and directly contact a portion of the upper surface 116U proximal to the end portion 116E₁, and a portion of the lower surface 116L proximal to the end portion 116E₁ of the conductive layer 116. The tunnel barrier layer 126 may further extend vertically to be arranged between the erase gate 122 and the control gate 120.

As mentioned above, the floating gate 112 may be electrically isolated from the neighboring conductive features, such as the substrate 104, the control gate 120, the select gate 124, and the erase gate 122. For example, the floating gate 112 may be electrically isolated from the substrate 104 by a gate dielectric layer 128. The gate dielectric layer 128 may further electrically isolate the select gate 124 and the erase gate 122 from the substrate 104.

An insulator layer 130 may be arranged between the control gate 120 and the floating gate 112. For example, the floating gate 112 may be electrically isolated from the control gate 120 by the insulator layer 130. In another example, the insulator layer 130 may overlay and directly contact the conductive layer 114 of the floating gate 112. The floating gate 112 may be electrically isolated from the select gate 124 and the erase gate 122 by the tunnel barrier layer 126 and a dielectric spacer 132, respectively. The control gate 120 may also be electrically isolated from the select gate 124 by at least the tunnel barrier layer 126 and from the erase gate 122 by the dielectric spacer 132.

In an embodiment of the disclosure, the NVM device 100 may further include a gate spacer 134 positioned adjacent to a side surface of the control gate 120 and a gate spacer 136 positioned adjacent to a laterally opposite side surface of the control gate 120. The control gate 120 may be positioned between the gate spacer 134 and the gate spacer 136 and may be in direct contact with at least a portion of the respective side surfaces of the gate spacers 134 and 136. Each gate spacer 134 and 136 may include a single-layered dielectric material or a multi-layered dielectric material. In this embodiment of the disclosure, each gate spacer 134 and 136 may include a multi-layered dielectric material of a dielectric material 138a and a dielectric material 138b.

To program the NVM device 100, a hot carrier injection (HCl) mechanism may be utilized. A predetermined voltage may be applied to select gate 124 to generate charges. A relatively higher voltage may be applied to the control gate 120 and the erase gate 122 to accelerate the charges from the source region 106 towards the drain region 108 through the channel region 110. The control gate 120 and the floating gate 112 may be capacitively coupled and induce a vertical electric field to pull, or inject, charges into the floating gate 112. As used herein, “capacitively coupled” and “capacitive coupling” indicate the transfer of energy by means of the capacitance between two conductive features, such as between the floating gate 112 and the control gate 120. The floating gate 112 may become sufficiently negatively charged and the NVM device 100 may be considered to be in a programmed state “0”.

As the width of the conductive layer 114 may be narrower than the width of the conductive layer 116, the portion of the dielectric spacer 132 between the conductive layer 114 and the select gate 124 may have a width relatively wider than that of the portion of the dielectric spacer 132 between the conductive layer 116 and the select gate 124. For example, as illustrated in FIG. 1, the portion of the dielectric spacer 132 between the conductive layer 114 and the select gate 124 may have a width W3, and the portion of the dielectric spacer 132 between the conductive layer 116 and the select gate 124 may have a width W4, and the width W3 is wider than the width W4. The width of the conductive layer 118 may also be narrower than the width of the conductive layer 116, and accordingly, the portion of the dielectric spacer 132 between the conductive layer 118 and the select gate 124 may also have a width relatively wider than the width W4. The relatively wider width of the dielectric spacer 132 advantageously minimizes undesirable capacitance coupling between the select gate 124 and the floating gate 112, thereby improving program efficiency of the NVM device 100.

To erase the programmed NVM device 100, a Fowler-Nordheim (FN) tunneling mechanism may be utilized. A sufficiently large potential difference may be applied between the floating gate 112 and the erase gate 122 such that an electric field may be induced to enable stored charges in the floating gate 112 to tunnel through the tunnel barrier layer 126 into the erase gate 122. The floating gate 112 may be sufficiently discharged of charges and may be considered to be in an erased state “1”.

The corner 116C₁ and the corner 116C₂ of the conductive layer 116 may advantageously improve the erase efficiency of the NVM device 100. For example, the corner 116C₁ and the corner 116C₂ of the conductive layer 116 may enhance the electric field during erase operation as the electric field generated at corner regions may be relatively stronger than that of non-corner regions. The stronger electric field may readily enhance the tunneling, or flow, of charges from the floating gate 112 to the erase gate 122 through the tunnel barrier layer 126, thereby improving the erase efficiency of the NVM device 100.

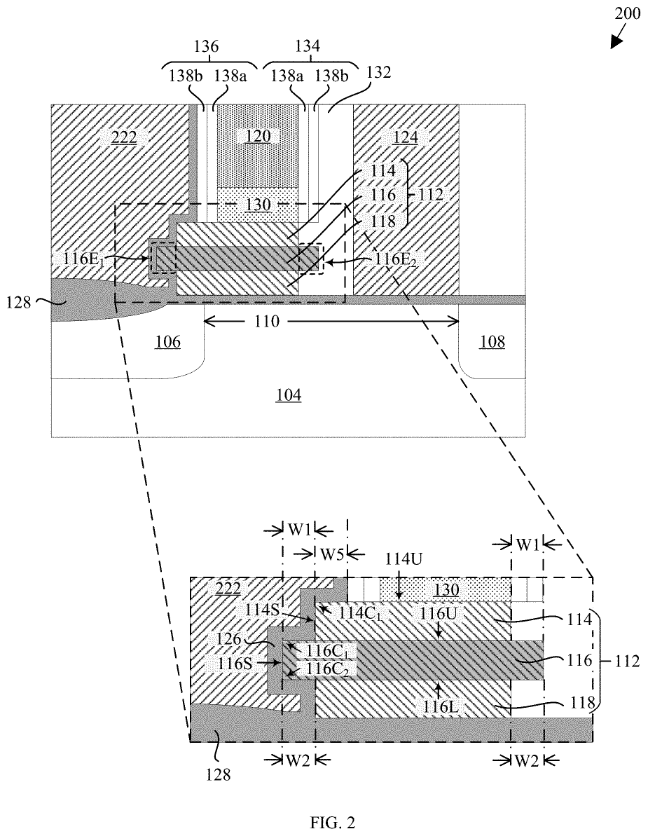

FIG. 2 is a cross-sectional view of an NVM device 200, according to another embodiment of the disclosure. The NVM device 200 is similar to the memory cell 102a of the NVM device 100 in FIG. 1, and thus common features are labeled with the same reference numerals and need not be discussed.

The NVM device 200 may include an erase gate 222. The erase gate 222 may be similar to the erase gate 122 of the NVM device 100. For example, the erase gate 222 may be at least partially arranged over the source region 106 and adjacent to the floating gate 112. The erase gate 222 may be at least partially arranged over the end portion 116E₁ of the conductive layer 116 of the floating gate 112 such that the erase gate 222 may overlay the corner 116C₁ and the corner 116C₂ of the conductive layer 116.

However, unlike the erase gate 122 of the NVM device 100, the erase gate 222 may further overlay a corner 114C₁ of the conductive layer 114 of the floating gate 112 as the conductive layer 114 may extend beyond the insulator layer 130 by a width W5.

The conductive layer 114 of the floating gate 112 may include a side surface 114S and an upper surface 114U, and the corner 114C₁ of the conductive layer 114 may be formed at the junction of the side surface 114S and the upper surface 114U. The corner 114C₁ of the conductive layer 114, along with the corner 116C₁ and the corner 116C₂ of the conductive layer 116, may further improve the erase efficiency of the NVM device 200. In this embodiment of the disclosure, the floating gate 112 may include three corners pointing towards the erase gate 222 for enhanced erase efficiency; the corner 114C₁ of the conductive layer 114, and the corner 116C₁ and the corner 116C₂ of the conductive layer 116.

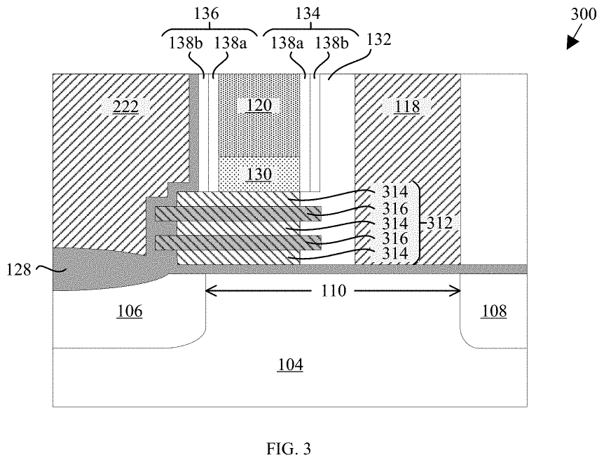

FIG. 3 is a cross-sectional view of an NVM device 300, according to yet another embodiment of the disclosure. The NVM device 300 is similar to the NVM device 200 in FIG. 2, and thus common features are labeled with the same reference numerals and need not be discussed.

The NVM device 300 may include a floating gate 312. The floating gate 312 may be similar to the floating gate 112 of the NVM device 200. For example, the floating gate 312 may be a multi-layered floating gate. However, unlike the floating gate 112 of the NVM device 200, the floating gate 312 may further include an alternating arrangement configuration of a conductive layer 314 and a conductive layer 316. For example, the floating gate 312 may include five conductive layers arranged in a 314-316-314-316-314 alternating arrangement configuration. In this embodiment of the disclosure, the floating gate 312 may include five corners pointing towards the erase gate 222 for enhanced erase efficiency.

The floating gate 312 may have a height substantially similar to that of the floating gate 112 of the NVM device 200. Accordingly, the conductive layer 314 and the conductive layer 316 may be relatively thinner than the conductive layer 114 and the conductive layer 116 of the floating gate 112.

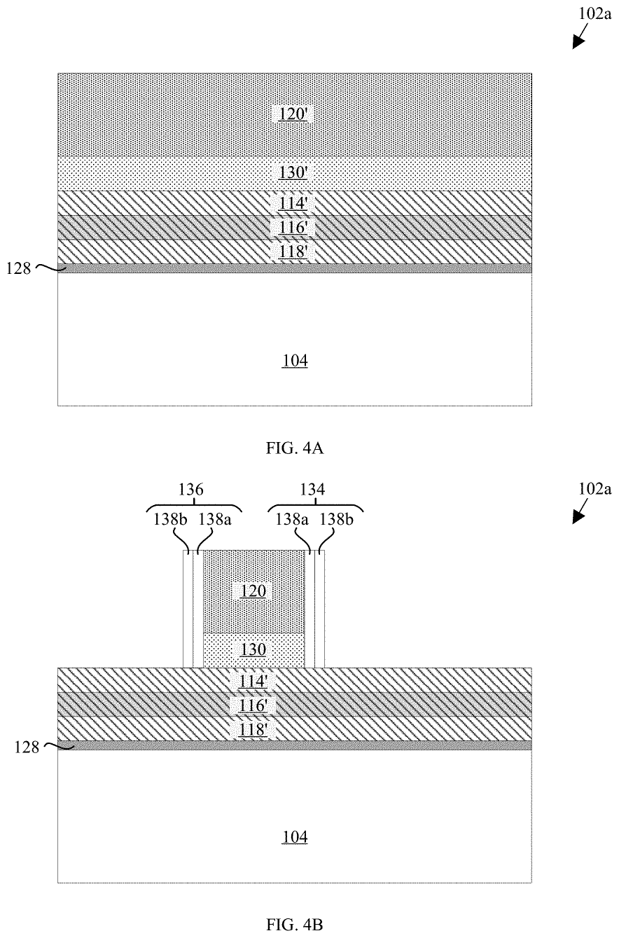

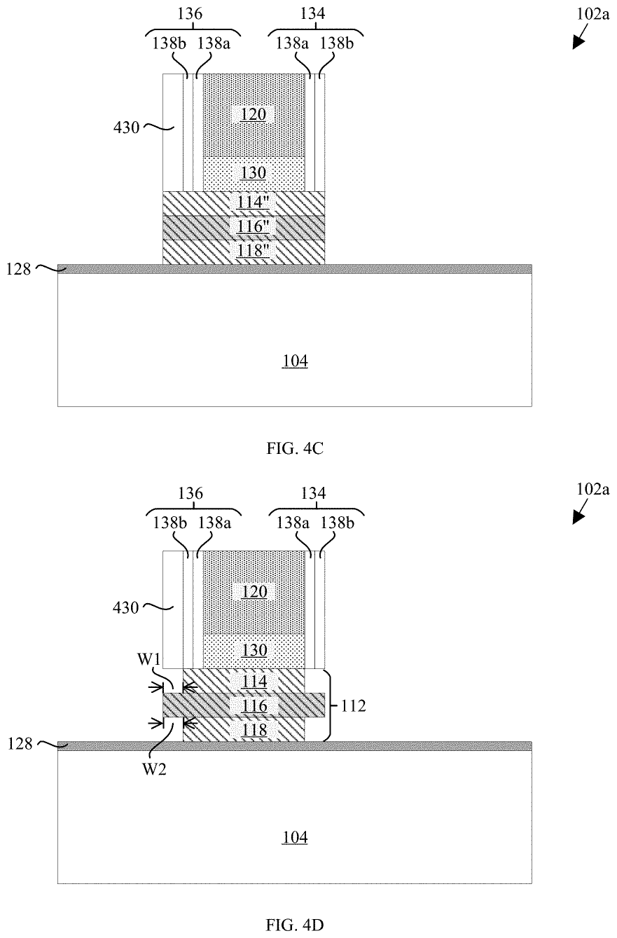

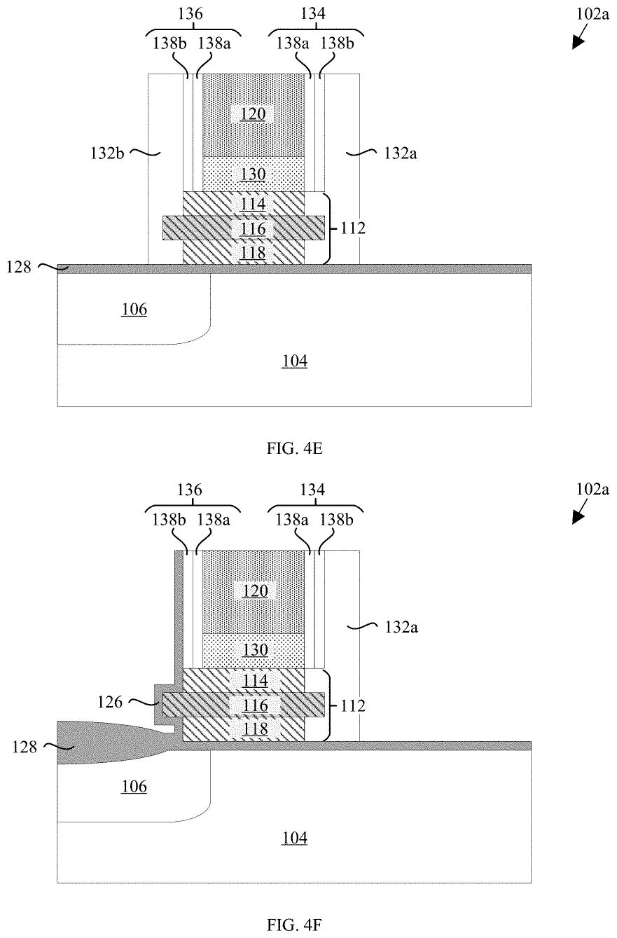

FIGS. 4A to 4F are cross-sectional views that illustrate an exemplary method of forming the memory cell 102a of the NVM device 100 in FIG. 1, according to an embodiment of the disclosure. Certain structures may be fabricated, for example, using known processes and techniques, and specifically disclosed processes and methods may be used to achieve individual aspects of the present disclosure.

As used herein, “deposition techniques” refer to the process of applying a material over another material (or the substrate). Exemplary techniques for deposition may include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning techniques” as used herein include deposition of material or photoresist, patterning, exposure, development, etching, cleaning, and/or removal of the material or photoresist as required in forming a described pattern, structure, or opening. Exemplary examples of techniques for patterning may include, but not limited to, wet etch photolithographic processes, dry etch photolithographic processes, or direct patterning processes.

The term “doping techniques” as used herein refers to an intentional introduction of impurities, i.e., dopants, into an intrinsic semiconductor material to alter its property, for example, modulating its electrical, optical, and/or structural properties. Exemplary techniques for doping may include, but not limited to, ion implantation or in-situ growth during epitaxial growth of semiconductor materials.

As illustrated in FIG. 4A, a substrate 104 may be provided. The substrate 104 may include a semiconductor material, such as silicon, silicon germanium, silicon carbide, other II-VI or III-V semiconductor compounds, and the like. Furthermore, the substrate 104 may be in a form of a bulk semiconductor substrate or a layered semiconductor substrate, such as a semiconductor-on-insulator (SOI) substrate.

A gate dielectric layer 128 may be formed over the substrate 104. The gate dielectric layer 128 may include an electrically insulative material, such as a dielectric material with a high dielectric constant; also may be referred to as a high-k dielectric material, or silicon dioxide. In an embodiment of the disclosure, the gate dielectric layer 128 may be deposited using a deposition technique.

A layer of conductive material 118′, a layer of conductive material 116′, and a layer of conductive material 114′ may be sequentially formed over the gate dielectric layer 128 using various deposition techniques. Each layer of conductive material 114′, 116′, and 118′ may be deposited to a substantially uniform and equal thickness. In an embodiment of the disclosure, each layer of conductive material 114′, 116′, and 118′ may have a thickness in a range of about 3 nm to about 7 nm.

The layer of conductive material 116′ may include a different conductive material from the layer of conductive material 114′ and the layer of conductive material 118′ such that the layer of conductive material 116′ may have a substantially lower etch selectivity with respect to the layer of conductive material 114′ and the layer of conductive material 118′. The layer of conductive material 114′ and the layer of conductive material 118′ may or may not include the same conductive material. In an embodiment of the disclosure, the layer of conductive material 114′ may include polycrystalline silicon germanium. In another embodiment of the disclosure, the layer of conductive material 116′ may include polycrystalline silicon. In yet another embodiment of the disclosure, the layer of conductive material 118′ may include polycrystalline silicon germanium.

A layer of insulator material 130′ may be formed over the layer of conductive material 114′ using a deposition technique. The layer of insulator material 130′ may include an electrically insulative hard mask material that may be suitable to protect underlying materials from potential damage caused during the fabrication process. In an embodiment of the disclosure, the layer of insulator material 130′ may include oxide-nitride-oxide (ONO), oxide-nitride (ON), silicon dioxide, silicon nitride, or combinations thereof.

A layer of gate material 120′ may be formed over the layer of insulator material 130′ using a deposition technique. The layer of gate material 120′ may include a conductive material, such as polycrystalline silicon.

FIG. 4B illustrates the memory cell 102a after forming an insulator layer 130 and a control gate 120, according to an embodiment of the disclosure. The layer of insulator material 130′ and the layer of gate material 120′ may be patterned using a patterning technique to form the insulator layer 130 and the control gate 120, respectively. The patterning technique may be a one-step or a multi-step process. Portions of the layer of conductive material 114′ may be exposed after performing the patterning technique.

A gate spacer 134 and a gate spacer 136 may be formed adjacent to laterally opposite side surfaces of the control gate 120. Each gate spacer 134 and 136 may include a multi-layered dielectric material, including a dielectric material 138a and a dielectric material 138b. A first layer of dielectric material (not shown) may be deposited over the memory cell, and a second layer of dielectric material (not shown) may be deposited over the first layer of dielectric material. A material removal technique may be performed to remove portions of the first and second layers of dielectric materials; the material removal technique being preferably an anisotropic etching process, to form the dielectric material 138a and the dielectric material 138b, respectively.

Each gate spacer 134 and 136 may include an electrically insulative dielectric material such as, but not limited to, silicon dioxide, silicon nitride, silicon oxynitride, combinations thereof, or other electrically insulative materials suitable to electrically isolate the control gate 120 from adjacent conductive features. In this embodiment of the disclosure, the dielectric material 138a may include an oxide material, such as silicon dioxide, and the dielectric material 138b may include a nitride material, such as silicon nitride.

FIG. 4C illustrates the memory cell 102a after forming a layer of conductive material 114″, a layer of conductive material 116″, and a layer of conductive material 118″, according to an embodiment of the disclosure. A sacrificial spacer 430 may be formed adjacent to the gate spacer 136. A dielectric material (not shown) may be deposited over the NVM device 100 using a deposition technique; the deposition technique being preferably a conformal deposition process. The conformal deposition process may include, but not limited to, an ALD process or a highly-conformal CVD process. A material removal technique may be performed to remove portions of the dielectric material; the material removal technique being preferably an anisotropic etching process, to form the sacrificial spacer 430 adjacent to the gate spacer 136, i.e., the gate spacer 134 that is at a laterally opposite side of the control gate 120 may be exposed after performing the material removal technique to form the sacrificial spacer 430. In an embodiment of the disclosure, the dielectric material may include silicon dioxide, silicon nitride, silicon oxynitride, or a combination thereof.

Using the sacrificial spacer 430 and the gate spacer 134 as masking features, the layers of conductive materials 114′, 116′, and 118′ may be patterned using a patterning technique to form the layers of conductive material 114″, 116″, and 118″, respectively, having substantially equal widths. Portions of the gate dielectric layer 128 may be exposed after performing the patterning technique.

FIG. 4D illustrates the memory cell 102a after forming a floating gate 112, according to an embodiment of the disclosure. A material removal technique may be performed on the layers of conductive materials 114″, 116″, and 118″; the material removal technique being preferably a highly selective isotropic etching process with a time-controlled duration, to form a conductive layer 114, a conductive layer 116, and a conductive layer 118, respectively, of which form the floating gate 112.

As mentioned above, the conductive layer 114 and/or the conductive layer 118 may have a substantially high etch selectivity with respect to the conductive layer 116. Accordingly, during the material removal technique, the conductive layer 114 and the conductive layer 118 may have a higher material removal rate as compared to the conductive layer 116 to form the conductive layer 114 and the conductive layer 118 having a width narrower than that of the conductive layer 116, i.e., the conductive layer 114 and the conductive layer 118 may be laterally etched to a greater extent than the conductive layer 116. For example, the conductive layer 116 may extend beyond the conductive layer 114 by a width W1. In another example, the conductive layer 116 may extend beyond the conductive layer 118 by a width W2. In an embodiment of the disclosure, the width W1 may have a range of about 10 nm to about 20 nm.

FIG. 4E illustrates the memory cell 102a after forming a source region 106, a dielectric spacer 132a, and a dielectric spacer 132b, according to an embodiment of the disclosure. The sacrificial spacer 430, as illustrated in FIG. 4D, may be removed using a material removal technique before forming the dielectric spacer 132a and the dielectric spacer 132b.

A dielectric spacer material (not shown) may be formed over the memory cell 102a using a deposition technique; the deposition technique being preferably a conformal deposition process. The dielectric spacer material may overlay the gate dielectric layer 128, the floating gate 112, the gate spacers 134, and the gate spacers 136. The dielectric spacer material may be patterned using a patterning technique to form the dielectric spacer 132a and the gate spacer 136b at laterally opposite sides of the floating gate 112. The dielectric spacer 132a and the gate spacer 136b may serve to protect the floating gate 112 during the formation of the source region 106.

The source region 106 may be formed in the substrate 104 by introducing dopants into the substrate 104 using a doping technique, such as an ion implantation process. In an embodiment of the disclosure, the source region 106 may be doped with N-type dopants, such as phosphorus, arsenic, or antimony.

FIG. 4F illustrates the memory cell 102a after forming a tunnel barrier layer 126, according to an embodiment of the disclosure. The dielectric spacer 132b, as illustrated in FIG. 4E, may be removed using a material removal technique before forming the tunnel barrier layer 126.

A tunnel barrier material (not shown) may be deposited using a deposition technique; the deposition technique being preferably a conformal deposition process. The tunnel barrier material may be deposited over the source region 106, overlying the gate dielectric layer 128, the floating gate 112, and the dielectric spacer 132a.

In an embodiment of the disclosure, the tunnel barrier layer 126 may be formed of a similar material as the gate dielectric layer 128, for example, silicon dioxide, though not necessarily. The tunnel barrier layer 126 and the portion of the gate dielectric layer 128 over the source region 106 may undergo a thermal process to form a relatively thicker gate dielectric layer 128, i.e., a local oxidation of silicon (LOCOS) structure, over the source region 106. Regions of the memory cell 102a that may be affected by the thermal process may be protected using a sacrificial material, such as a photoresist layer.

The memory cell 102a may undergo further fabrication steps to form an erase gate 122, a select gate 124, and a drain region 108. A conductive material (not shown) may be deposited over the tunnel barrier layer 126 and the gate dielectric layer 128 using a deposition technique, and patterned using a patterning technique to form the erase gate 122 over the source region 106 and the select gate 124 at a laterally opposite side of the floating gate 112 from the erase gate 122. The conductive material may be conformally deposited and may fill the region under the conductive line 110b. A portion of the erase gate may acquire a concave profile adjacent to the floating gate 112, as illustrated in FIG. 1.

In an embodiment of the disclosure, the conductive material may include polysilicon, amorphous silicon, metals or alloys, for example, TiN, TaN, or W, or combinations thereof. However, the erase gate 122 and the select gate 124 may not necessarily be formed of the same conductive material. Accordingly, the erase gate 122 and the select gate 124 may be formed separately and not concurrently as described above.

The drain region 108 may be formed in the substrate 104 such that the floating gate 112 and the select gate 124 may be arranged between the source region 106 and the drain region 108. The drain region 108 may be formed by introducing dopants into the substrate 104 using a doping technique, such as an ion implantation process. In an embodiment of the disclosure, the drain region 108 may be doped with N-type dopants, such as phosphorus, arsenic, or antimony.

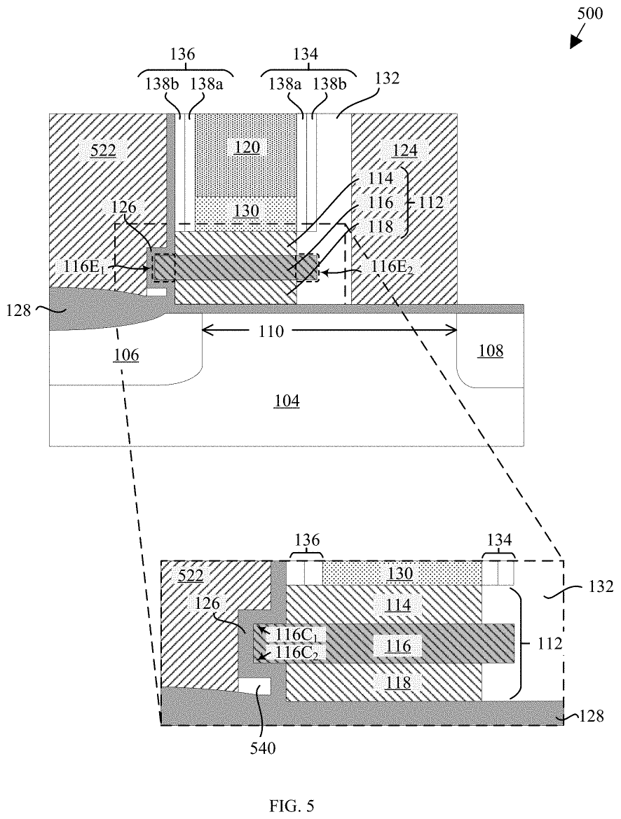

FIG. 5 is a cross-sectional view of a memory cell 500, according to an alternative embodiment of the disclosure. The memory cell 500 is similar to the memory cell 102a of the NVM device 100 of FIG. 1, and thus common features are labeled with the same reference numerals and need not be discussed.

The memory cell 500 may include an erase gate 522 and an air gap 540. The air gap 540 may be formed during the deposition of the conductive material to form the erase gate 522, where the conductive material may not underfill the region under the conductive layer 116, thereby forming the air gap 540. The air gap 540 may be formed between the erase gate 522 and the conductive layer 118, and advantageously minimizes undesirable capacitance between the erase gate 522 and the floating gate 112, thereby improving erase efficiency of the memory cell 500.

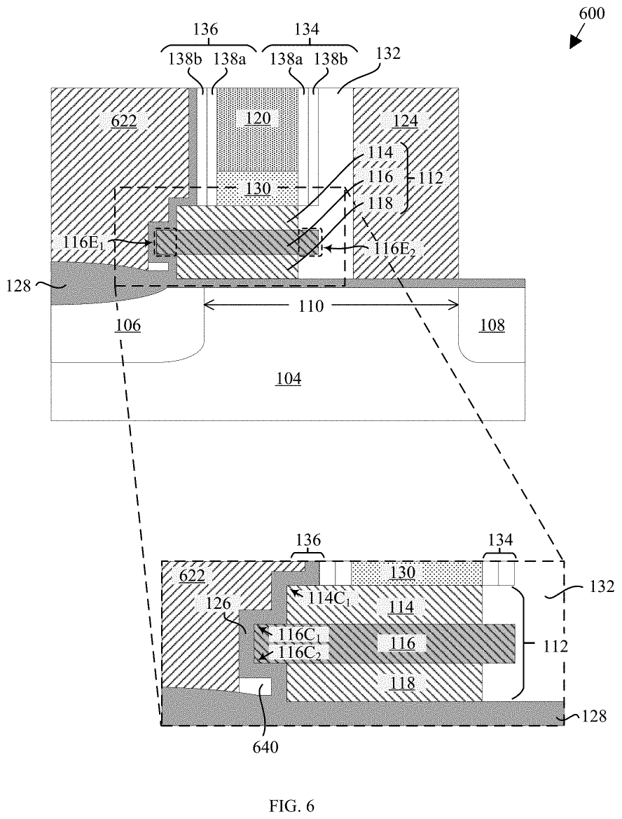

FIG. 6 is a cross-sectional view of an NVM device 600, according to another alternative embodiment of the disclosure. The NVM device 600 is similar to the NVM device 200 of FIG. 2, and thus common features are labeled with the same reference numerals and need not be discussed.

The NVM device 600 may include an erase gate 622 and an air gap 640. The air gap 640 may be formed during the deposition of the conductive material to form the erase gate 622, when the conductive material may not underfill the region under the conductive layer 116, thereby forming the air gap 640. The air gap 640 may be formed between the erase gate 622 and the conductive layer 118, and advantageously minimizes undesirable capacitance between the erase gate 622 and the floating gate 112, thereby improving erase efficiency of the NVM device 600.

As presented in the above disclosure, NVM devices with multi-layered floating gates and methods of forming the same are presented. The multi-layered floating gate may include at least a first conductive layer and a second conductive layer underlying the first conductive layer and having a width wider than the first conductive layer. The first conductive layer and the second conductive layer may have a substantially high etch selectivity such that the material of the first conductive layer may be removed at a higher rate than the material of the second conductive layer during a material removal technique.

The multi-layered floating gate may have enhanced erase efficiency. For example, the second conductive layer of the multi-layered floating gate may extend beyond the first conductive layer and forms corners at the end portions. The corners may enhance the electric field during an erase operation as the electric field generated at corner regions may be relatively stronger than that of non-corner regions. The stronger electric field may readily enhance the tunneling, or flow, of charges from the floating gate to an erase gate, thereby improving the erase efficiency of the NVM device.

The multi-layered floating gate may further have enhanced program efficiency. For example, the multi-layered floating gate may be electrically isolated from a select gate by a dielectric spacer. A portion of the dielectric spacer adjacent to the first conductive layer may have a width relatively wider than the portion of the dielectric spacer adjacent to the second conductive layer. The relatively wider width of the dielectric spacer advantageously minimizes undesirable capacitance coupling between the select gate and the multi-layered floating gate, thereby improving program efficiency of the NVM device.

The above disclosure discloses an embodiment where the multi-layered floating gate includes polycrystalline silicon and polycrystalline silicon germanium. Such a floating gate may advantageously enable longer data retention duration due to the formation of a quantum well in the bandgap of the floating gate. Furthermore, the polycrystalline silicon and polycrystalline silicon germanium may have close electron affinity such that uniform sheet resistance and higher endurance may be achieved when compared to single-layered floating gates.

Due to the improved performance of the NVM devices having multi-layered floating gates, such NVM devices may be used in simultaneous in-logic memory (SLIM) computing applications where the multi-layered floating gate architecture substantially reduce the data transfer speed between the computer processors and the NVM devices as compared to the conventional von Neumann NVM device architecture.

The terms “upper”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,”, “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of ninety degrees plus or minus a normal tolerance of the semiconductor industry.

While several exemplary embodiments have been presented in the above detailed description of the device, it should be appreciated that a number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A non-volatile memory device, comprising:
a substrate comprising a source region and a drain region, and a channel region between the source region and the drain region;
a floating gate over the channel region, the floating gate comprises a first conductive layer and a second conductive layer underlying the first conductive layer; and
a gate adjacent to the floating gate.

2. The non-volatile memory device of claim 1, wherein the second conductive layer comprises an end portion and the end portion extends beyond the first conductive layer.

3. The non-volatile memory device of claim 2, wherein the end portion comprises a corner pointing towards the gate, and the gate overlays the corner.

4. The non-volatile memory device of claim 1, wherein the first conductive layer has a substantially high etch selectivity with respect to the second conductive layer.

5. The non-volatile memory device of claim 4, wherein the first conductive layer comprises polycrystalline silicon germanium.

6. The non-volatile memory device of claim 4, wherein the second conductive layer comprises polycrystalline silicon.

7. The non-volatile memory device of claim 1, wherein the first conductive layer and the second conductive layer have substantially equal thicknesses.

8. The non-volatile memory device of claim 1, wherein the gate is an erase gate.

9. The non-volatile memory device of claim 1, wherein the gate has a concave side surface adjacent to the floating gate.

10. A non-volatile memory device, comprising:
a substrate comprising a source region and a drain region, and a channel region between the source region and the drain region;
a floating gate over the channel region, the floating gate comprises a first conductive layer having a first width, and a second conductive layer having a second width underlying the first conductive layer, the first width is narrower than the second width; and
a first gate adjacent to a first side of the floating gate; and
a second gate adjacent to a second side of the floating gate, and the second side is laterally opposite the first side.

11. The non-volatile memory device of claim 10, further comprising a tunnel barrier layer between the first gate and the floating gate, and the tunnel barrier layer overlays the floating gate.

12. The non-volatile memory device of claim 10, further comprising a spacer between the second gate and the floating gate.

13. The non-volatile memory device of claim 12, wherein the spacer has a first width adjacent to the first conductive layer and a second width adjacent to the second conductive layer, and the first width is wider than the second width.

14. The non-volatile memory device of claim 10, wherein the floating gate further comprises a third conductive layer underlying the second conductive layer.

15. The non-volatile memory device of claim 14, wherein the third conductive layer has a third width, and the third width is substantially equal to the first width of the first conductive layer.

16. The non-volatile memory device of claim 15, further comprises an air gap between the first gate and the third conductive layer.

17. A method of forming a non-volatile memory device, comprising:
forming a source region in a substrate;
forming a drain region in the substrate and spaced apart from the source region by a channel region therebetween;
forming a floating gate having a first width and a second width over the channel region; and
forming a first gate and a second gate at laterally opposite sides of the floating gate.

18. The method of claim 17, wherein forming the floating gate comprises:
depositing a first conductive layer over the substrate;
depositing a second conductive layer over the substrate, the second conductive layer underlying the first conductive layer; and
performing an isotropic etching process to form the first conductive layer having the first width and the second conductive layer having the second width.

19. The method of claim 18, further comprises forming a tunnel barrier layer between the floating gate and the first gate, and the tunnel barrier layer conformally overlays the floating gate.

20. The method of claim 17, wherein forming the floating gate comprises:
depositing a first conductive layer over the substrate;
depositing a second conductive layer over the substrate, the second conductive layer underlying the first conductive layer;
depositing a third conductive layer over the substrate, the third conductive layer underlying the second conductive layer; and
performing an isotropic etching process to form the first conductive layer having the first width, the second conductive layer having the second width, and the third conductive layer having a third width substantially equal to the first width.
